(19) United States
(12) Patent Application Publication
(10) Pub. No.: US 2025/0113623 A1
(43) Pub. Date: Apr. 3, 2025

(54) PROCESS FOR MANUFACTURING A PHOTOVOLTAIC MODULE AND CORRESPONDING MANUFACTURING INSTALLATION

(71) Applicants: Commissariat à l'énergie atomique et aux énergies alternatives, Paris (FR); Centre Technique Industriel de la Plasturgie et des composites, Levallois-Perret (FR); Université Savoie Mont Blanc, Chambery (FR)

(72) Inventors: Tatiana DUIGOU, Grenoble Cedex 09 (FR); Pascal FRANCESCATO, Le Bourget-Du-Lac Cedex (FR); Julien GAUME, Grenoble Cedex 09 (FR)

(73) Assignees: Commissariat à l'énergie atomique et aux énergies alternatives, Paris (FR); Centre Technique Industriel de la Plasturgie et des composites, Levallois-Perret (FR); Université Savoie Mont Blanc, Chambery (FR)

(21) Appl. No.: 18/728,755

(22) PCT Filed: Jan. 9, 2023
(86) PCT No.: PCT/FR2023/050025

§ 371 Date: Jul. 12, 2024

(30) Foreign Application Priority Data
Jan. 14, 2022 (FR) FR22/00323

(51) Int. Cl. H10F 19/80; B29C 70/70; B29L 31/34

(52) U.S. Cl. CPC H10F 19/804; B29C 70/70; B29L 2031/34

(57) ABSTRACT

The manufacture of a photovoltaic module includes providing a first layer having a skew shape, manufacturing a second layer having a skew shape, and then placing a stack further including photovoltaic cells and at least one encapsulating material in an assembly mold varying between a closure configuration delimiting a predetermined air gap and an opening configuration. In an assembly step, where the closure configuration of the assembly mold is adopted, the temperature within the stack is maintained at an operating temperature comprised between 70° C. and 180° C., and preferably between 80° C. and 150° C., during an assembly period adapted as a function of the at least one encapsulating material so that the at least one encapsulating material undergoes melting at least partially and to create an encapsulating assembly capable of adhering to the plurality of photovoltaic cells and to the first layer and/or to the second layer.

### TECHNICAL FIELD OF THE INVENTION

The present invention relates to the field of manufacture of photovoltaic modules, which include a set of photovoltaic cells electrically connected to each other, and preferably so-called “crystalline” photovoltaic cells, that is to say which are based on single-crystal or polycrystalline silicon.

More specifically, the invention concerns a method for manufacturing a photovoltaic module and a manufacturing facility comprising the material elements for implementing such a method.

The invention can be implemented for numerous applications, in particular civil and/or military applications, for example autonomous and/or embedded applications, being particularly concerned with applications which require the use of lightweight and glass plate-free photovoltaic modules, in particular with a mass per unit area of less than 5 kg/m², and with low thickness, in particular smaller than 5 mm. In particular, it can thus be applied to buildings such as homes or industrial premises (tertiary, commercial, etc.), for example for the construction of their roofs, for street furniture design, for example for public lighting, road signing or even electric car charging, or even be used for mobile applications (solar mobility), in particular for integration on vehicles, such as cars, buses or boats, drones, airships, among others.

The invention thus proposes a solution making it possible to manufacture a lightweight photovoltaic module while being sufficiently resistant and very advantageously having skew shapes. In the rest of the document, a so-called skew shape is a non-planar, bent, curved, domed or hollow shape, and more generally having a general three-dimensional shape not oriented along a main plane.

### PRIOR ART

A photovoltaic module is an assembly of photovoltaic cells arranged side by side between a first transparent layer forming a front face of the photovoltaic module and a second layer forming a rear face of the photovoltaic module.

The first layer forming the front face of the photovoltaic module is advantageously transparent to enable the photovoltaic cells to receive a light flux. It is traditionally made from a single glass plate, in particular tempered glass, having a thickness typically comprised between 2 and 4 mm, conventionally in the range of 3 mm.

The second layer forming the rear face of the photovoltaic module can be made based on glass, metal or plastic, among others. It is often formed by a polymeric structure based on an electrical insulating polymer, for example of the polyethylene terephthalate (PET) or polyamide (PA) type, which can be protected by at least one layer based on fluoropolymers, such as polyvinyl fluoride (PVF) or polyvinylidene fluoride (PVDF), and having a total thickness in the range of 300-400 μm.

The photovoltaic cells can be electrically connected to each other by front and rear electrical contact elements, called connecting conductors, and formed for example by tinned copper strips, respectively arranged against the front (faces facing the front face of the photovoltaic module intended to receive a light flux) and rear (faces facing the rear face of the photovoltaic module) faces of each of the photovoltaic cells, or even only on the rear face for the IBC (“Interdigitated Back Contact”) type photovoltaic cells.

It should be noted that IBC type photovoltaic cells are structures for which the contacts are made on the rear face of the cell in the form of interdigitated combs. They are for example described in document U.S. Pat. No. 4,478,879A.

Furthermore, the photovoltaic cells, located between the first and second layers respectively forming the front and rear faces of the photovoltaic module, can be encapsulated. Conventionally, the selected encapsulant corresponds to a polymer of the elastomer (or rubber) type, and can for example consist of the use of two poly(ethylene-vinyl acetate) (EVA) layers (or films) between which the photovoltaic cells and the cell connecting conductors are arranged. Each encapsulant layer may have a thickness of at least 0.2 mm and a Young's modulus typically comprised between 2 and 400 MPa at room temperature.

A conventional example of photovoltaic module 1 including crystalline photovoltaic cells 4 is partially and schematically represented, respectively in cross-section in FIG. 1 and in exploded view in FIG. 2.

As previously described, the photovoltaic module 1 includes a front face 2, generally made of transparent tempered glass with a thickness of approximately 3 mm, and a rear face 5, for example consisting of an opaque or transparent single-layer or multi-layer polymer sheet, having a Young's modulus greater than 400 MPa at room temperature.

The photovoltaic cells 4, electrically connected to each other by connecting conductors 6 and immersed between two front 3a and rear 3b layers of encapsulating material both forming an encapsulating assembly 3, are located between the front 2 and rear 5 faces of the photovoltaic module 1.

FIG. 1A further represents a variant of the example of FIG. 1 in which the photovoltaic cells 4 are of the IBC type, the connecting conductors 6 being only arranged against the rear faces of the photovoltaic cells 4.

Furthermore, FIGS. 1 and 2 also represent the junction box 7 of the photovoltaic module 1, intended to receive the wiring necessary for operating the module. Conventionally, this junction box 7 is made of plastic or rubber, and has complete sealing.

Usually, the method for producing the photovoltaic module 1 includes a step called vacuum lamination of the previously described different layers, at a temperature greater than or equal to 120° C., or even 140° C., or even 150° C., and lower than or equal to 170° C., typically comprised between 145 and 165° C., and for a duration of the lamination cycle of at least 10 minutes, or even 15 minutes.

During this lamination step, the layers of encapsulating material 3a and 3b undergo melting and come to enclose the photovoltaic cells 4, at the same time as adhesion is created at all the interfaces between the layers, namely between the front face 2 and the front layer of encapsulating material 3a, the front layer of encapsulating material 3a and the front faces 4a of the photovoltaic cells 4, the rear faces 4b of the photovoltaic cells 4 and the rear layer of encapsulating material 3b, and the rear layer of encapsulating material 3b and the rear face 5 of the photovoltaic module 1. The obtained photovoltaic module 1 is then framed, typically by means of an aluminum profile.

Such a structure has now become a standard which has a significant mechanical resistance thanks to the use of a front face 2 made of thick glass and the aluminum frame, allowing it, in particular and in most cases, to comply with the IEC 61215 and IEC 61730 standards.

However, such a photovoltaic module 1 has the disadvantage of having a high mass, in particular a mass per unit area of approximately 10 to 12 kg/m², and is thus not suitable for certain applications where lightness is a priority.

This high mass of the photovoltaic module 1 mainly comes from the presence of thick glass, with a thickness of approximately 3 mm, to form the front face 2, the density of the glass being in fact high, in the range of 2.5 kg/m²/mm thickness, and of the aluminum frame. To be able to withstand the stresses during manufacturing and also for safety reasons, for example due to the risk of cuts, the glass is tempered. However, the industrial infrastructure of the thermal tempering is configured to process glass of at least 3 mm thick. Moreover, the choice of having a glass thickness of approximately 3 mm is also linked to a standardized mechanical pressure resistance of 5.4 kPa. Ultimately, the glass alone represents practically 70% of the mass of the photovoltaic module 1, and more than 80% with the aluminum frame around the photovoltaic module 1.

Also, in order to obtain a significant reduction in the mass of a photovoltaic module to enable its use in new applications demanding in terms of lightness and shaping, there is a need to find an alternative solution to the use of a thick glass on the front face of the module, using new plastic or composite materials with the primary aim of significantly reducing the surface mass.

Thus, sheets of polymers, such as polycarbonate (PC), polymethyl methacrylate (PMMA), polyvinylidene fluoride (PVDF), ethylene tetrafluoroethylene (ETFE), ethylene chlorotrifluoroethylene (ECTFE), or fluorinated ethylene propylene (FEP), can represent an alternative to glass. However, when only replacing the glass with such a thin sheet of polymers is considered, the photovoltaic cell becomes highly vulnerable to shock, mechanical load and differential expansion.

An alternative is the use of reinforcing fiber-based composite materials on the front panel, replacing standard glass. The mass gain can be significantly important despite reduced transparency.

The replacement of the glass on the front face of the photovoltaic modules has been the subject of patents or patent applications in the prior art. We can thus cite in this respect the patent application FR2955051A1, the American patent application US2005/0178428A1 or the international applications WO2008/019229A2 and WO2012/140585A1. Other patents or patent applications have described the use of composite materials, such as for example the European patent application EP2863443A1, or the international applications WO2018/076525A1, WO2019/006764A1 and WO2019/006765A1.

However, none of these currently known solutions makes it possible to achieve the manufacture of a photovoltaic module which is, in addition to being lightweight (therefore without glass) and resistant as required by the needs of the practical applications and administrative standards, shaped according to a skew shape, in particular typically shaped with a curvature which can be identical or different along two distinct axes of a reference frame associated with the photovoltaic module, and moreover produced in a simple, rapid, efficient and economical manner, and ideally using only recyclable materials.

### OBJECT OF THE INVENTION

The invention therefore aims to at least partially remedy the aforementioned needs and the drawbacks relating to the prior art embodiments.

Hence, the aim of the invention is, according to one of its aspects, a method for manufacturing a photovoltaic module (10), comprising the following steps:
E1) providing a first layer having a skew, transparent shape and intended to form a front face of the photovoltaic module intended to receive a light flux,
E2) manufacturing a second layer having a skew shape and intended to form a rear face of the photovoltaic module,
E3) placing a stack in an assembly mold, implemented after steps E1 and E2, in which:
i. the stack comprises the first layer, a plurality of photovoltaic cells arranged side by side and electrically connected to each other, the second layer and at least one encapsulating material, the stack being such that the at least one encapsulating material and the plurality of photovoltaic cells are located between the first and second layers,
ii. and the assembly mold has an ability to occupy a closure configuration and comprises a first rigid mold part delimiting a first impression with skew shape complementary to the skew shape of the first layer and a second rigid mold part delimiting a second impression with skew shape complementary to the skew shape of the second layer, the first mold part and the second mold part being such that, in the closure configuration of the assembly mold, the first mold part and the second mold part are spaced apart by a predetermined air gap and delimit between them a cavity capable of receiving the stack,
E4) assembly, implemented after step E3, in which the closure configuration of the assembly mold being adopted, the temperature within the stack is maintained at an operating temperature comprised between 70° C. and 180° C., and preferably between 80° C. and 150° C., during an assembly period adapted as a function of the at least one encapsulating material so that the at least one encapsulating material undergoes melting at least partially and to create an encapsulating assembly capable of adhering on the one hand to the plurality of photovoltaic cells and on the other hand to the first layer and/or to the second layer.

Some preferred but non-limiting aspects are as follows.

According to one embodiment, the first layer is formed of a thermoplastic material.

According to one embodiment, the first layer is a first composite material formed based on a first polymer and first fibers,
the first polymer being selected from: ethylene chlorotrifluoroethylene (ECTFE), fluorinated ethylene propylene (FEP), ethylene tetrafluoroethylene (ETFE), polyvinylidene fluoride (PVDF), polymethyl methacrylate (PMMA), polycarbonate (PC), polyethylene terephthalate (PET), polyamide (PA), styrene-acrylonitrile (SAN), polystyrene (PS),
and the first fibers being selected from glass, aramid fibers and/or natural fibers.

According to one embodiment, the first polymer is polycarbonate (PC) or styrene-acrylonitrile (SAN) and the first fibers are glass fibers.

According to one embodiment, at least one layer selected from the first layer and the second layer is rigid.

According to one embodiment, step E1 comprises the following steps:
E11) preparing the first composite material, in the form of a fiber-reinforced thermoplastic composite plate,
E12) placing the first composite material in a preparation mold, the preparation mold having an ability to occupy a closure configuration and comprising two rigid preparation mold parts and delimiting two preparation impressions with skew shape complementary to the skew shape of the first layer, the two preparation mold parts being such that, in the closure configuration of the preparation mold, the two preparation mold parts are spaced apart by a predetermined air gap and delimit between them a cavity capable of receiving the first composite material,
E13) heating the first composite material to a temperature greater than or equal to the glass transition temperature of the first composite material, the difference between said temperature and the glass transition temperature being comprised between 0 and 20° C.,
E14) applying to the first composite material, by the two preparation mold parts, a mechanical pressure greater than or equal to 5 bars, in particular greater than 10 bars and preferably in the range of 15 bars, by placing the preparation mold in the closure configuration, while controlling the cooling until reaching a temperature comprised between 50° C. and 150° C.

According to one embodiment, the two preparation mold parts consist respectively of the first and second mold parts of the assembly mold, step E1 comprising a step E10 consisting in modifying the air gap separating the two preparation mold parts in the closure configuration of the preparation mold in step E14, relative to the air gap present in step E4 in the closure configuration of the assembly mold.

According to one embodiment, the first layer has a thickness smaller than 1.5 mm, preferably in the range of 0.5 mm.

According to one embodiment, the second layer is formed of a thermoplastic material.

According to one embodiment, the second layer is a second composite material formed based on a second polymer and fibers, in particular formed from a prepreg,
the second polymer being selected from: polycarbonate (PC), polymethyl methacrylate (PMMA), thermoplastic polyurethane (TPU), polyetheretherketone (PEEK), polyetherketoneketone (PEKK), polyphenylene sulfide (PPS), polyamide (PA), polystyrene (PS),
and the fibers being selected from glass, carbon, aramid fibers and/or natural fibers, in particular hemp, linen and/or silk.

According to one embodiment, the second polymer is thermoplastic polyurethane (TPU), polycarbonate (PC), or polyamide (PA), and the second fibers are glass fibers.

According to one embodiment, step E2 comprises the following steps:
E21) providing the second composite material,
E22) placing the second composite material in a manufacturing mold, the manufacturing mold having an ability to occupy a closure configuration and comprising two rigid manufacturing mold parts and delimiting two manufacturing impressions with skew shape complementary to the skew shape of the second layer, the two manufacturing mold parts being such that, in the closure configuration of the manufacturing mold, the two manufacturing mold parts are spaced apart by a predetermined air gap and delimit between them a cavity capable of receiving the second composite material,
E23) heating the second composite material to a temperature substantially equal (within 10° C.) to the glass transition temperature of the second material,
E24) applying to the second composite material, by the two manufacturing mold parts, a mechanical pressure greater than or equal to 5 bars, in particular in the range of 10 bars, by placing the manufacturing mold in the closure configuration, while controlling the cooling until reaching a temperature comprised between 50° C. and 150° C.

According to one embodiment, the two manufacturing mold parts consist respectively of the first and second mold parts of the assembly mold, step E2 comprising a step E20 consisting in modifying the air gap separating the two manufacturing mold parts in the closure configuration of the manufacturing mold in step E24, relative to the air gap present in step E4 in the closure configuration of the assembly mold.

According to one embodiment, the second layer has a thickness smaller than 2 mm, preferably in the range of 1.5 mm.

According to one embodiment, during step E4, the pressure of the gas present in the cavity of the assembly mold is maintained, during the assembly period, below −0.5 bar, preferably between −0.7 bar and −1 bar.

According to one embodiment, step E4 comprises a step E41 during which the first and second mold parts (22, 24) of the assembly mold exert, on the stack, a mechanical pressure lower than or equal to 5 bars.

According to one embodiment, step E41 begins after the operating temperature is reached, after a predetermined non-zero period comprised between 0.5 min and 2 min and preferably in the range of 1 min.

According to one embodiment, step E41 is implemented for a period comprised between 30 s and 10 min.

According to one embodiment, the manufacturing method comprises a step E5 consisting in heating the assembly mold to a temperature greater than or equal to the operating temperature, step E5 being implemented before step E4.

According to one embodiment, the manufacturing method comprises a step E6 consisting in heating the stack by means of an infrared heat source, step E6 being carried out after step E3 and before step E4.

According to one embodiment, the manufacturing method comprises a step E7 of cooling the stack, said step E7 being performed while the first and second mold parts of the mold assembly exert, on the stack, a mechanical pressure lower than or equal to 5 bars.

### SUMMARY DESCRIPTION OF THE DRAWINGS

Other aspects, purposes, advantages and features of the invention will better appear on reading the following detailed description of preferred embodiments thereof, given as a non-limiting example, and made with reference to the appended drawings in which:

FIG. 1 represents, in cross-section, a conventional example of a photovoltaic module including crystalline photovoltaic cells,

FIG. 1A represents a variant of the example of FIG. 1 in which the photovoltaic cells are of the IBC type,

FIG. 2 represents, in exploded view, the photovoltaic module of FIG. 1,

FIG. 3 represents, in a flowchart, the different steps of an example of a manufacturing method according to the invention,

FIG. 4 represents, in perspective, an example of a photovoltaic module which can be obtained by the implementation of a manufacturing method according to the invention,

FIG. 5 represents, in perspective, an example of an assembly mold capable of being used for the implementation of a manufacturing method according to the invention,

FIG. 6 is a schematic visualization of the springback of an example of a photovoltaic module produced by the implementation of an example of a manufacturing method according to the invention.

FIG. 7 represents a curve illustrating an example of evolution, with different successive phases, of the temperature adopted by the mold assembly as a function of time in an example of a manufacturing method according to the invention,

FIG. 8 schematically represents the behavior of the assembly mold and the stack during the different phases corresponding to those defined in FIG. 7.

### DETAILED DESCRIPTION

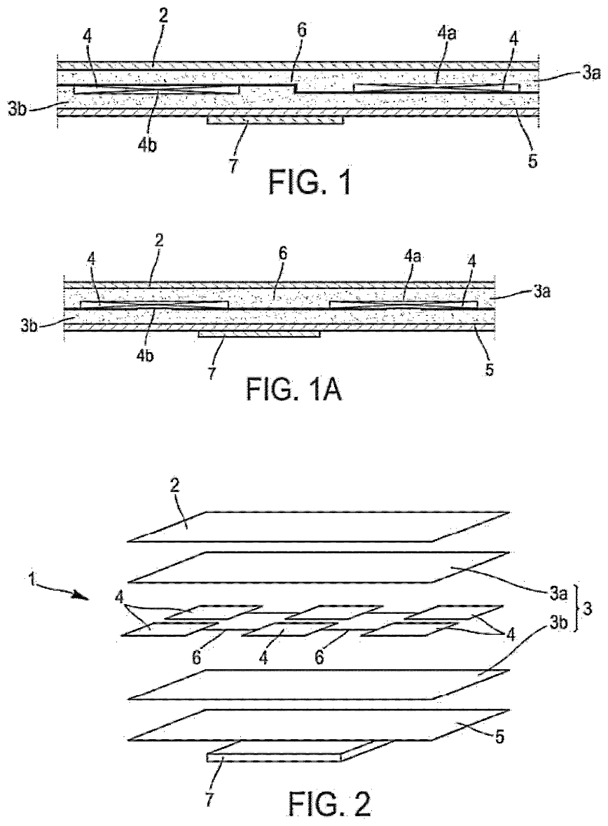

FIGS. 1, 1A and 2 have already been described in the section relating to the prior art.

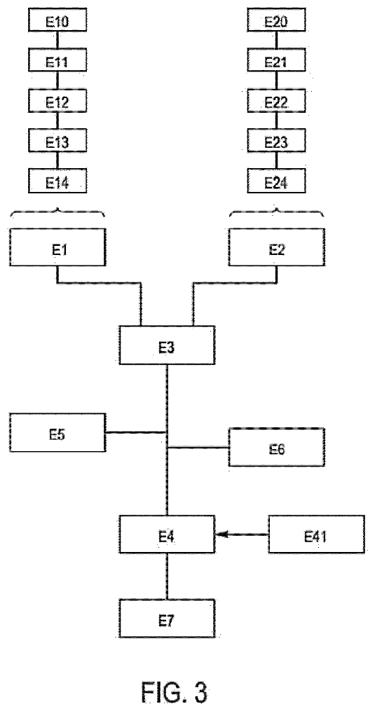

FIG. 3 represents in a flowchart the different steps of an example of a manufacturing method according to the invention.

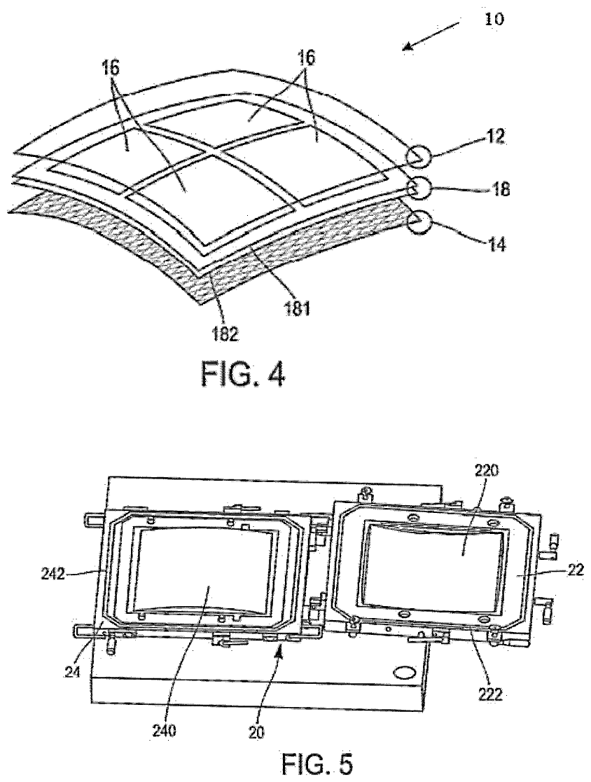

The implementation of these steps makes it possible in particular to obtain a photovoltaic module 10, an example of which is represented in FIG. 4, with the particularity of having a general skew, non-planar shape, this term “skew shape” having been previously defined in the section relating to the prior art.

The photovoltaic module 10 which can be obtained comprises at least:
a first layer 12 having a skew, transparent shape and intended to form a front face of the photovoltaic module 10 intended to receive a light flux,
a second layer 14 having a skew shape and intended to form a rear face of the photovoltaic module 10,
a plurality of photovoltaic cells 16 arranged side by side and electrically connected to each other,
an encapsulating assembly 18 ensuring encapsulation of all or part of the photovoltaic cells 16.

In this skew-shaped, therefore non-planar photovoltaic module 10, the photovoltaic cells 16 and the encapsulating assembly 18 are arranged between the first layer 12 and the second layer 14. These arrangements are represented in FIG. 4, in exploded view.

Generally, the first layer 12 is formed in one or several parts, namely it can be single-layer or multi-layer. The second layer 14 can also be formed in one or several parts, namely it can be single-layer or multi-layer.

The term “transparent” means that the first layer 12 forming the front face of the photovoltaic module 10 is at least partially transparent to visible light, allowing at least approximately 80% of this light to pass through. In particular, the optical transparency, between 300 and 1200 nm, of the first layer 12 can be greater than 80%.

Moreover, by the term “encapsulant”, it should be understood that the plurality of photovoltaic cells 16 is arranged in a volume, for example hermetically sealed against liquids, at least partially formed by at least two layers of encapsulating material(s), joined together, at the end of the manufacturing method which will be described, to form the encapsulating assembly 18.

Indeed, initially, that is to say before the implementation of step E4 which will be described later, the encapsulating assembly 18 consists of at least one layer of an encapsulating material 181 located between the plurality of photovoltaic cells 16 and the first layer 12 and at least one layer of an encapsulating material 182 located between the plurality of photovoltaic cells 16 and the second layer 14. However, this is only during step E4 that this layer encapsulating material 181, 182 will undergo at least partial melting to form, after cooling, the solidified encapsulating assembly 18 and in which the photovoltaic cells 16 are embedded.

In the example of FIG. 4, the first layer 12 is shaped with a curvature which may be identical or different along two distinct axes of a reference frame associated with the photovoltaic module 10. Complementarily, the second 14 is shaped with a curvature which may be identical or different along two distinct axes of a reference frame associated with the photovoltaic module 10. It may in particular be provided that the curvatures are identical for the first layer 12 and for the second layer 14, guaranteeing a similarity of shapes for the first and second layers 12, 14 and facilitating their superposition within the stack.

The photovoltaic cells 16 can be selected from: single-crystal silicon (c-Si) and/or polycrystalline silicon (mc-Si)-based homojunction or heterojunction photovoltaic cells and/or IBC type photovoltaic cells, and/or photovoltaic cells comprising at least one material from amorphous silicon (a-Si), microcrystalline silicon (μC-Si), cadmium telluride (CdTe), copper-indium selenide (CIS) and copper-indium/gallium diselenide (CIGS), perovskites, among others. Furthermore, the photovoltaic cells 16 can have a thickness comprised between 1 and 300 μm, in particular between 1 and 200 μm, and advantageously between 70 μm and 160 μm.

The photovoltaic module 10 may also include a junction box (not visible in FIG. 4), intended to receive the wiring necessary for operating the photovoltaic module 10 and which can be positioned on the front face or on the rear face of the module, preferably on the front face. The way in which this junction box is made is not in itself restrictive and any known technique can be used.

Moreover, the spacing between two neighboring, or even consecutive or adjacent, photovoltaic cells 16 may be greater than or equal to 1 mm, in particular comprised between 1 and 30 mm, and preferably equal to 2 mm.

As can be seen in FIG. 3, the manufacturing method comprises a step E1 of providing the first layer 12 in such a way that it has its skew shape and its transparency characteristics. The manufacturing method also comprises a step E2 of manufacturing the second layer 14 in such a way that it also has its skew shape. It is possible to carry out step E1 before step E2, or vice versa. Alternatively, it is possible to carry out all or part of step E1 overlapping all or part of step E2.

In general, the way in which step E1 is carried out and the way in which step E2 is carried out are not in themselves restrictive as long as they are each implemented with parameters adapted to the result to be obtained in each of them, in particular in order to obtain at the end of the manufacturing method a photovoltaic module 10 having the desired lightness and resistance characteristics, typically in order to meet the IEC 61215 and IEC 61730 standards.

Non-limiting but advantageous implementations of steps E1 and E2 will be described later.

The manufacturing method also comprises a step E3 of placing a stack (described below) in an assembly mold 20. Step E3 is implemented after steps E1 and E2. In one embodiment, the stack is directly made in the assembly mold 20. Alternatively, the stack is at least partially made outside the assembly mold 20 before being placed and possibly finalized in the assembly mold 20. An example of such an assembly mold 20 is illustrated in FIG. 5, which is adapted to obtain the photovoltaic module 10 of FIG. 4.

During step E3, the stack comprises the first layer 12, the plurality of photovoltaic cells 16 arranged side by side and electrically connected to each other, the second layer 14 and at least one encapsulating material 181, 182. As previously indicated, the at least one encapsulating material 181, 182 and the plurality of photovoltaic cells 16 are located between the first and second layers 12, 14.

To implement step E3, the assembly mold 20 is configured so as to have an ability to occupy a closure configuration, in particular by varying between this closure configuration (not illustrated) and an opening configuration (illustrated in FIG. 5). The assembly mold 20 generally comprises a first rigid mold part 22 delimiting a first impression 220 having a skew shape complementary to the skew shape of the first layer 12. The assembly mold 20 also comprises a second rigid mold part 24 delimiting a second impression 240 having a skew shape complementary to the skew shape of the second layer 14. Depending on the design of the assembly mold 20, the passage from the closure configuration to the opening configuration and vice versa can be done by a relative movement between the first mold part 22 and the second mold part 24, this relative movement being a combination between:
a translation along a first axis of the reference frame associated with the photovoltaic module 10 to be obtained and oriented in the direction in which the different layers and elements of the stack are stacked,
and/or a pivoting about a second axis of this reference frame oriented transversely to the first axis.

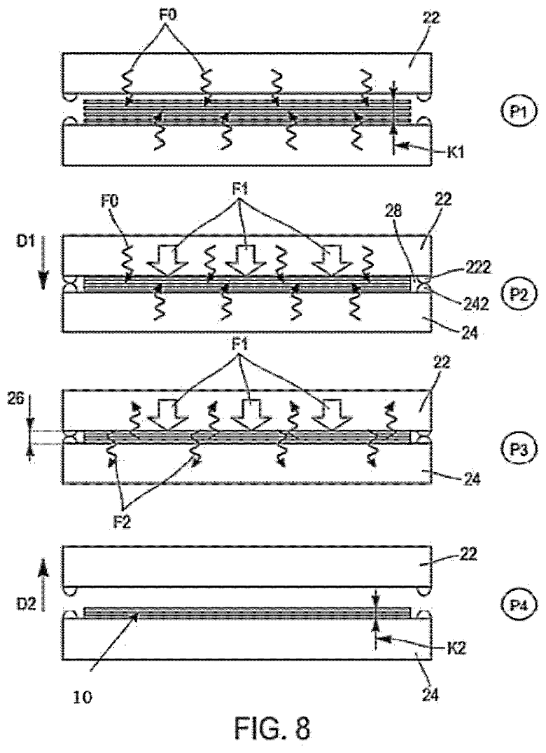

The first mold part 22 and the second mold part 24 are such that, in the closure configuration of the assembly mold 20, the first mold part 22 and the second mold part 24 are spaced apart by a first predetermined air gap 26 and delimit between them a cavity 28 capable of receiving the stack defined above. The predetermined air gap 26 and the cavity 28 are shown schematically in FIG. 8 detailed below in which it should be noted that a first seal 222 of the first mold part 22 comes into contact against a second seal 242 of the second mold part 24 in order to ensure sealing such that, in the closure configuration, the cavity 28 can be placed in vacuum conditions compared with the ambient pressure outside the assembly mold 20. It may be possible to have a vacuum in the cavity without pressurizing the part.

Placing the first predetermined air gap 26 in the closure configuration can result from the mechanical abutment of a first stop secured to the first mold part 22 against a second stop secured to the second mold part 24, the mechanical abutment of these first and second stops being accompanied by the establishment of the sealing described in the previous paragraph by means of the first and second seals 222, 242.

Preferably, the assembly mold 20 comprises adjustment elements configured so as to adjust the value of the predetermined air gap 26, ultimately making it possible to adapt to the value of the thickness of the stack and the thickness of the manufactured photovoltaic module 10.

According to one embodiment, these adjustment elements can be selected from:
elements making it possible to vary the position of the first stop relative to the rest of the first mold part 22,
elements making it possible to vary the position of the second stop relative to the rest of the second mold part 24,
wedges with variable heights capable of being positioned between the first stop and the second stop in the closure configuration of the assembly mold 20.

The manufacturing method then comprises an assembly step E4, implemented after step E3. During step E4, the closure configuration of the assembly mold 20 is adopted and the temperature within the stack is maintained at an operating temperature (denoted Tfonc in FIG. 7) comprised between 70° C. and 180° C., preferably between 80° C. and 150° C., during an assembly period adapted as a function of the at least one encapsulating material 181, 182 so that the at least one encapsulating material 181, 182 undergoes melting at least partially and to create the encapsulating assembly 18 capable of adhering on the one hand to the plurality of photovoltaic cells 16 and on the other hand to the first layer 12 and/or to the second layer 14.

The manufacturing method described herein therefore has the particularity of providing the first layer 12 and the second layer 14 of the photovoltaic module 10 before the latter is assembled in accordance with step E4. In other words, the first and second layers 12, 14 are not manufactured at the same time as the assembly of the different layers of the photovoltaic module 10 obtained by the manufacturing method occurs.

This is particularly advantageous because it is then possible to plan for carrying out step E1 and step E2 under pressure and/or temperature conditions which would not be tolerated by step E4. In particular, it is possible to implement step E1 and step E2 under conditions where the temperature would be comprised between 180 and 300° C. and where the mechanical pressure applied respectively to the first layer 12 during step E1, and to the second layer 14 during step E2, would be greater than 5 bars. However, such conditions would not be tolerated (due to the skew shape of all the plies or layers of the stack) by the at least one encapsulating material 181, 182 unless it results in creep of the latter likely to generate real problems both in the resistance of the photovoltaic module 10 and in its homogeneity and repeatability of the manufacturing method, with displacement of the photovoltaic cells and breaking of the electrical connections or cells.

Moreover, the use of an assembly mold 20 having two mold parts 22, 24 made of an advantageously rigid material and configured to adopt a predetermined air gap makes it possible to guarantee the presence of an air gap having a value that is perfectly repeatable and independent of the mechanical pressure applied by the assembly mold 20 to the photovoltaic module 10 and independently of the pressure of the gas present in the cavity 28. These arrangements guarantee excellent repeatability of the assembly step E4 and good reliability of the manufactured photovoltaic modules 10.

These arrangements are to be distinguished from commonly implemented techniques where the manufacture of a planar-shaped photovoltaic module is carried out by a lamination where the planar layers forming the front and rear faces of the photovoltaic module are at least partially manufactured at the same time as the encapsulating assembly is formed and where a tarpaulin is present to apply a uniform pressure during pressurization of the stack in the case of skew shapes. The implementation of such techniques for skew shapes would involve great difficulties since the application of a uniform pressure by the tarpaulin to a stack with non-uniform thickness, due to a phenomenon of creep of the encapsulating material towards low points of the mold resulting from the heating conditions, would lead to the inevitable obtaining of a photovoltaic module having a non-uniform thickness. The use of an assembly mold 20 in accordance with steps E3 and E4 makes it possible to address these issues.

The manufacturing method allows manufacturing a photovoltaic module 10 which is:
compatible with a wide range of mass per unit area ranging from a few kg/m² up to several tens of kg/m²,
resistant as required by the needs of practical applications and administrative standards, typically the IEC 61215 and IEC 61730 standards,
skew-shaped, in particular typically shaped with a curvature which may be identical or different along two distinct axes of a reference frame associated with the photovoltaic module.

It should be noted that the skew shape of the photovoltaic module 10, in itself, can contribute to providing high resistance to the manufactured photovoltaic module 10.

The manufacturing method further has the advantage of being very quick and easy to implement, making it easily automatable on a large scale, of being efficient and economical, of offering excellent repeatability and good reliability of the manufactured photovoltaic modules.

The manufacturing method has the additional advantage of being able to be implemented using only recyclable materials.

Preferably, the at least one encapsulating material 181, 182 has a thickness comprised between 100 and 2000 μm and is a thermoplastic elastomer selected from: polyolefin, silicone, thermoplastic polyurethane, polyvinyl butyral, functional polyolefin, ionomer.

Preferably, the first layer 12 is made of a thermoplastic material, which offers an eco-design advantage in view of the recyclability, as well as theoretically faster shaping because it does not require an incompressible crosslinking time. According to one embodiment, the numerous tests and simulations carried out by the Applicant have led to the conclusions that the first layer 12 may in particular be a first composite material formed based on a first polymer and first fibers, where:
the first polymer is selected from: ethylene chlorotrifluoroethylene (ECTFE), fluorinated ethylene propylene (FEP), ethylene tetrafluoroethylene (ETFE), polyvinylidene fluoride (PVDF), polymethyl methacrylate (PMMA), polycarbonate (PC), polyethylene terephthalate (PET), polyamide (PA), styrene-acrylonitrile (SAN), polystyrene (PS)
and the first fibers are selected from glass, aramid fibers and/or natural fibers.

Among the numerous tests, it was possible to determine that it is very advantageous to provide that the first polymer is polycarbonate (PC) or styrene-acrylonitrile (SAN) and that the first fibers are glass fibers.

Nevertheless, it is possible to adapt the manufacturing method so that the first layer 12 is formed of a thermosetting material.

In accordance with FIG. 3, according to a particular embodiment, step E1 comprises the following steps:
E11) preparing (or supplying) the first composite material, in the form of a fiber-reinforced thermoplastic composite plate,
E12) placing the first composite material from step E11 in a preparation mold, the preparation mold having an ability to occupy a closure configuration and comprising two rigid preparation mold parts and delimiting two preparation impressions with skew shape complementary to the skew shape of the first layer, the two preparation mold parts being such that, in the closure configuration of the preparation mold, the two preparation mold parts are spaced apart by a second predetermined air gap and delimit between them a cavity capable of receiving the first composite material,
E13) heating the first composite material to a temperature greater than or equal to the glass transition temperature of the first composite material, the difference between said temperature and the glass transition temperature being comprised between 0 and 20° C. (typically a temperature comprised between 180° C. and 300° C. and preferably between 180° C. and 200° C.),
E14) applying to the first composite material, by the two preparation mold parts, a mechanical pressure greater than or equal to 5 bars, in particular greater than 10 bars and preferably in the range of 15 bars, by placing the preparation mold in the closure configuration, while controlling the cooling until reaching a temperature comprised between 50° C. and 150° C.

An advantage of implementing these steps is to then facilitate assembly. Alternatively, it could be a simple thermoforming where only steps E11 to E13 would be present and where the overpressure of step E14 would not be applied.

The preparation mold can be of any type as long as it is adapted to the implementation of steps E11 to E14. It is not represented in itself and is not restrictive. Those skilled in the art can use all their knowledge and the appropriate techniques for the implementation of steps E11 to E14.

The first thermoplastic composite material in the form of such a fiber-reinforced thermoplastic composite plate is also known, in the relevant technical field, by the terminology “organosheet”. In other words, an organosheet is an assembly of already compacted composite plies.

The first composite material used in step E11 may have a surface mass comprised between 25 and 600 g/m², in particular between 300 and 600 g/m², typically in the range of 450 g/m².

In certain variants, it is possible to provide that the two preparation mold parts consist respectively of the first and second mold parts 22, 24 of the assembly mold 20, step E1 then comprising a step E10 consisting in modifying the air gap separating the two preparation mold parts in the closure configuration of the preparation mold in step E14, relative to the predetermined air gap 26 present in step E4 in the closure configuration of the assembly mold 20. This modification of the air gap as indicated here can be carried out via the adjustment elements which have been previously described.

An advantage is to be able to use the assembly mold 20 as a preparation mold usable in step E1, in order to limit parts and overall costs. Another advantage is to be able to avoid or limit transfers between step E1 and step E3. However, particularly in mass-production applications, it is entirely possible for the preparation mold used in step E1 to be distinct from the assembly mold 20 used in step E4, enabling mass production on lines using assembly-line stations.

Advantageously, the first layer 12 has a thickness smaller than 1.5 mm, preferably in the range of 0.5 mm. An advantage is to improve the transparency of the first layer 12 as much as possible: the smaller the thickness, the better the optical transmission.

The manufacturing method detailed in this document, carried out in step E4 in an assembly mold 20, in particular closed and for example under a hot press, and which makes it possible to reach the pressure and temperature ranges required for assembly in accordance with step E4, also makes it possible to reach the pressure and temperature ranges required for the compaction of the first thermoplastic composite material during step E1, without causing any disturbing creep of the encapsulating materials 181, 182 located between the first and second layers 12, 14 due to a temperature which would otherwise be excessive. This is necessary to enable the shaping, into the desired skew shape for the first layer 12, of the first thermoplastic composite material and accommodates the integration of the photovoltaic cells 16. Generally, it is not necessarily essential to provide a hot press, in the sense that the heating means can be either internal or external to the assembly mold tools.

According to a particular embodiment, step E13 can be carried out before step E12, by means of an infrared heating system, step E14 then being carried out using a preparation mold potentially at room temperature.

In addition, preferably, the second layer 14 is formed of a thermoplastic material, which offers an eco-design advantage in view of the recyclability, as well as theoretically faster shaping because it does not require an incompressible crosslinking time. In addition, this type of material is generally known for its capacity to dissipate the impact energy better than thermosetting materials. According to one embodiment, the numerous tests and simulations carried out by the Applicant have led to the conclusions that the second layer 14 may in particular be a second composite material formed based on a second polymer and fibers, in particular formed from a prepreg, where:
the second polymer is selected from: polycarbonate (PC), polymethyl methacrylate (PMMA), thermoplastic polyurethane (TPU), polyetheretherketone (PEEK), polyetherketoneketone (PEKK), polyphenylene sulfide (PPS), polyamide (PA), polystyrene (PS),
and the fibers are selected from glass, carbon, aramid fibers and/or natural fibers, in particular hemp, linen and/or silk.

Among the numerous tests, it was possible to determine that it is very advantageous to provide that the second polymer is thermoplastic polyurethane (TPU), polycarbonate (PC), or polyamide (PA), and that the second fibers are glass fibers.

Nevertheless, it is possible to adapt the manufacturing method so that the second layer 14 is formed of a thermosetting material.

In accordance with FIG. 3, according to a particular embodiment, step E2 comprises the following steps:
E21) providing the second composite material,
E22) placing the second composite material from step E21 in a manufacturing mold, the manufacturing mold having an ability to occupy a closure configuration and comprising two rigid manufacturing mold parts and delimiting two manufacturing impressions with skew shape complementary to the skew shape of the second layer, the two manufacturing mold parts being such that, in the closure configuration of the manufacturing mold, the two manufacturing mold parts are spaced apart by a third predetermined air gap and delimit between them a cavity capable of receiving the second composite material,
E23) heating the second composite material to a temperature substantially equal (within 10° C.) to the glass transition temperature of the second material (typically a temperature comprised between 180° C. and 300° C. and preferably between 220° C. and 260° C.),
E24) applying to the second composite material, by the two manufacturing mold parts, a mechanical pressure greater than or equal to 5 bars, in particular in the range of 10 bars, by placing the manufacturing mold in the closure configuration, while controlling the cooling until reaching a temperature comprised between 50° C. and 150° C.

An advantage of implementing these steps is to then facilitate assembly. Alternatively, it could be a simple thermoforming where only steps E21 to E23 would be present and where the overpressure of step E24 would not be applied.

The manufacturing mold can be of any type as long as it is adapted to the implementation of steps E21 to E24. It is not represented in itself and is not restrictive. Those skilled in the art can use all their knowledge and the appropriate techniques for the implementation of steps E21 to E24.

In certain variants, it is possible to provide that the two manufacturing mold parts consist respectively of the first and second mold parts 22, 24 of the assembly mold 20, step E2 then comprising a step E20 consisting in modifying the air gap separating the two manufacturing mold parts in the closure configuration of the manufacturing mold in step E24, relative to the predetermined air gap 26 present in step E4 in the closure configuration of the assembly mold 20. This modification of the air gap as indicated here can be carried out via the adjustment elements which have been previously described.

An advantage is to be able to use the assembly mold 20 as a manufacturing mold usable in step E2, in order to limit parts and overall costs. Another advantage is to be able to avoid or limit transfers between step E2 and step E3. However, particularly in mass-production applications, it is entirely possible that the manufacturing mold used in step E2 is distinct from the assembly mold 20, enabling mass production on lines using assembly-line stations.

For example, the second layer 14 has a thickness smaller than 2 mm, preferably in the range of 1.5 mm. This thickness enables a high resistance, particularly to external impacts such as hail for example.

The manufacturing method detailed in this document, carried out in step E4 in the assembly mold 20, typically closed and under a hot press, and which makes it possible to reach the pressure and temperature ranges required for assembly in accordance with step E4, also makes it possible to reach the pressure and temperature ranges required for the compaction of the second thermoplastic composite material during step E2, without causing any disturbing creep of the encapsulating materials 181, 182 located between the first and second layers 12, 14 due to a temperature which would otherwise be excessive. This is necessary to enable the shaping, into the desired skew shape for the second layer 14, of the second thermoplastic composite material and accommodates the integration of the photovoltaic cells 16.

According to one embodiment, step E23 is carried out before step E22. Alternatively, steps E23 and E24 are carried out at least partially simultaneously, for example by associating a hot press with the manufacturing mold.

According to a particular embodiment, during step E4, the pressure of the gas present in the cavity 28 of the assembly mold 20 is maintained, during the assembly period, below −0.5 bar, preferably between −0.7 bar and −1 bar. In other words, the E4 step is carried out under conditions close to a vacuum, to avoid defects in the final part (bubble, delamination, etc.).

Preferably, step E4 comprises a step E41 during which the first and second mold parts 22, 24 of the assembly mold 20 exert, on the stack, a mechanical pressure lower than or equal to 5 bars. This mechanical pressure, identified by the arrows F1 in FIG. 8 during phases P2 and P3, can be obtained by the fact that the assembly mold 20 is associated with a press capable of exerting this mechanical pressure, for example a hot press additionally adapted to the heating required for the implementation of step E4.

Thus, step E4 is preferably carried out at a pressure lower than 5 bars and a temperature comprised between 70 and 180° C., preferably between 80° C. and 150° C., which temperature enables the integration of the photovoltaic cells 16 into the encapsulating assembly 18. The temperature of this implementation must be carefully adjusted to avoid as much as possible the creep of the encapsulating assembly 18, promoted by the skew shape of the photovoltaic module 10. Likewise, the air gap 26 of the assembly mold 20 must be accurately adjusted so as not to damage the photovoltaic cells 16.

Preferably, step E41 begins after the operating temperature Tfonc (see FIG. 7) is reached, after a predetermined non-zero period comprised between 0.5 min and 2 min and preferably in the range of 1 min. This period is for example visible in FIG. 7 and denoted Δ. In practice, the operating temperature Tfonc can correspond to the melting temperature of the encapsulant. This non-zero duration allows time to draw the vacuum in the cavity and to enable the thermal diffusion of the temperature of the mold into the core of the part to soften the encapsulant.

Alternatively, and even if this presents a little more risk of breakage due to a lack of fluidity of the encapsulant when it has just passed the glass transition temperature, it remains possible that step E41 could begin as soon as the operating temperature Tfonc mentioned in connection with step E4 is reached.

According to a preferred embodiment, step E41 is implemented during a period comprised between 30 s and 10 min. This duration must again be carefully adjusted to avoid as much as possible the creep of the encapsulating assembly 18, promoted by the skew shape of the photovoltaic module 10, once the encapsulating materials have melted sufficiently to penetrate between the photovoltaic cells 16 and to be able to adhere, after cooling, to the first layer 12, to the second layer 14 and to the photovoltaic cells 16.

Generally, it is advantageous to plan for step E4 to be as short as possible to optimize the cycle time, while taking care, of course, to adjust the temperature and duration parameters in order to achieve the result defined for step E4 with respect to the encapsulating assembly 18 to be obtained, in particular depending on the nature and thickness of the at least one encapsulating material 181, 182.

According to a particular embodiment, the manufacturing method comprises a step E5 consisting in heating the assembly mold 20 to a temperature greater than or equal to the operating temperature Tfonc, step E5 being implemented before step E4.

Alternatively to step E5 or in combination therewith, the manufacturing method may comprise a step E6 consisting in heating the stack by means of an infrared heat source, step E6 being carried out after step E3 and before step E4.

Finally, the manufacturing method comprises a step E7 of cooling the stack, said step E7 being performed while the first and second mold parts 22, 24 of the assembly mold 20 exert, on the stack, a mechanical pressure lower than or equal to 5 bars. The mechanical pressure applied during step E7, during which in particular the two mold parts 22, 24 of the assembly mold 20 undergo a decrease in temperature and during which the photovoltaic module 10, as resulting from step E4, transfers heat to the assembly mold 20 to cool it, may be different from or equal to the mechanical pressure F1 exerted during step E41 described above, as required. This step E7 can possibly be carried out in a mold other than the molds used in the other previous steps, provided however that the appropriate air gap is retained. The pressure must be maintained at a minimum.

As described above, the first predetermined air gap 26 used to implement step E4 is preferably at least equal to a value equal to the sum of the thicknesses of each ply or layer belonging to the stack minus a certain gap included in a range comprised between 0.1 and 0.3 mm and preferably equal to 0.2 mm, and preferably at most equal to the sum of the thicknesses of each ply or layer belonging to the stack.

FIGS. 7 and 8 represent the different situations with four successive phases P1 to P4 of an example of a production method taking up the previously listed general teachings, these phases P1 to P4 being associated in particular with the implementation of step E4.

These successive phases P1 to P4 are in particular applied to a stack comprising the first layer 12, the photovoltaic cells 16 sandwiched between two encapsulating materials 181, 182, and the second layer 14, where the first layer 12 and the second layer 14 each have a skew shape, in particular typically shaped with a curvature which can be identical or different along two distinct axes of a reference frame associated with the photovoltaic module, and in addition possibly produced using only recyclable materials.

In a first phase P1, the temperature of the assembly mold 20 is increased. That is why, in phase P1, the curve illustrated in FIG. 7 (which represents the evolution of the temperature (ordinate) of the assembly mold 20 as a function of time (abscissa)) is in the form of a profile that increases over time, for example in a rectilinear manner. For example, the assembly mold 20 is associated with a hot press and its temperature increases at a speed of 4° C./min, until reaching a nominal temperature at the end of phase P1. This nominal temperature, which can be comprised between 80° C. and 150° C., is here strictly higher than the previously mentioned operating temperature Tfonc. It should be noted that phase P1 can be initiated after the implementation of step E3, which then implies that the stack (which then has a thickness denoted E1) is already placed between the two mold parts 22, 24 of the assembly mold 20. The heat input to the stack due to the heating phenomenon of the assembly mold 20 is shown schematically by the arrows F0. Alternatively, the assembly can be carried out outside the assembly mold 20, and simultaneously with the heating of the assembly mold 20, thus saving time, the stack then being deposited in the already hot assembly mold 20.

Then the second phase P2 begins, which concretely corresponds to the implementation of step E41. The time lag between the moment when the operating temperature Tfonc was reached and the start of phase P2, corresponds to the already described period Δ, comprised between 0.5 min and 2 min and preferably in the range of 1 min. To implement phase P2, the two mold parts 22, 24 undergo a relative bringing together shown schematically by the arrow D1, until they are separated from each other by a distance equal to the value of the first predetermined air gap 26. In this relative bringing together of the mold parts 22, 24, the assembly mold 20 exerts the mechanical pressure (for example approximately 5 bars), shown schematically by the arrows F1, mentioned in connection with step E41, which implies a compression of the stack present in the cavity 28 of the assembly mold 20. The stack then undergoes a reduction in its thickness, which passes from the value K1 to a value denoted K2. Throughout phase P2, the assembly mold 20 is maintained at the nominal temperature (That is why, in phase P2, the curve illustrated in FIG. 7 is in the form of a profile that is constant over time) and continues to heat the stack, which explains the presence of the arrows F0 in phase P2 in FIG. 8. Phase P2 is implemented during a period comprised between 30 s and 10 min, in particular between 3 min and 5 min and preferably in the range of 4 min. This duration must be carefully adjusted to avoid as much as possible the creep of the encapsulating assembly 18, promoted by the skew shape of the photovoltaic module 10, once the at least one encapsulating material 181, 182 has melted sufficiently to penetrate between the photovoltaic cells 16 and to be able to adhere, after cooling, to the first layer 12, to the second layer 14 and to the photovoltaic cells 16.

Then the third phase P3 begins, during which the temperature of the assembly mold 20 is reduced and that is why, in phase P3, the curve illustrated in FIG. 7 is in the form of a profile that decreases over time, for example in a rectilinear manner. This is the previously described implementation of step E7. For example, the temperature of the assembly mold 20 decreases at a speed of 8° C./min, until reaching the initial temperature at the start of phase P1. The transfer heat from the photovoltaic module 10 to the assembly mold 20 is shown schematically by the arrows F2. Moreover, throughout phase P3, a mechanical pressure continues to be exerted by the assembly mold 20. The mechanical pressure applied while the two mold parts 22, 24 of the assembly mold 20 undergo the decrease in temperature can be equal to the mechanical pressure exerted during the previously described phase P2 (that is why in phase P3 in FIG. 8 the mechanical pressure is shown schematically by the same arrows F1 as during phase 2), or may be different depending on needs.

Finally, the fourth phase P4 begins, during which the two mold parts 22, 24 undergo a relative moving away, shown schematically by the arrow D2, until they are at a distance from each other that is strictly greater than the value of the first predetermined air gap 26. In this relative moving away of the mold parts 22, 24, the assembly mold 20 releases the previously exerted mechanical pressure and the photovoltaic module 10 remains in its skew shape thus obtained and with the thickness E2, except for a potential springback phenomenon.

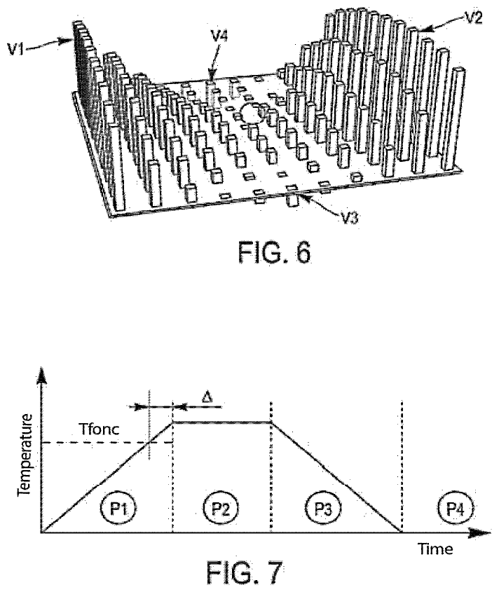

The method which has just been described was implemented for an example of a photovoltaic module and FIG. 6 represents a schematic visualization of the springback of the photovoltaic module thus produced.

To obtain the photovoltaic module in FIG. 6, the following stack was used (starting from the front face to the rear face):
a first composite material, in the form of a thermoplastic composite plate based on glass fiber-reinforced polycarbonate, which is transparent and has a surface mass of 450 g/m², intended to form the first layer 12 at the end of the method (two plies made of polycarbonate and glass fibers for a total thickness of 0.5 mm or three plies made of polycarbonate and glass fibers for a total thickness of 0.75 mm can in particular be provided),
a transparent encapsulating material made of thermoplastic polyurethane with a thickness of 620 μm,
single-crystal silicon photovoltaic cells measuring 125×125 mm²,
a transparent encapsulating material made of thermoplastic polyurethane with a thickness of 620 μm,
a second composite material in the form of a laminate, for example with 8 plies, alternating thermoplastic polyurethane and glass fibers, with a surface mass of 575 g/m² and a thickness of 2 mm, intended to form the second layer 14 at the end of the method.

In this example, the value of the curvature to be obtained along a first axis of curvature was 1 meter while the curvature to be obtained along a second axis of curvature, perpendicular to the first axis of curvature, was 2 meters.

From FIG. 6, it can be seen that the values V1 and V2 of the springback at points of the photovoltaic module symmetrically arranged along the second axis of curvature are substantially equal: the measurements V1 and V2 are respectively equal to 2.3 and 2.4 mm. Complementarily, the values V3 and V4 of the springback at points of the photovoltaic module symmetrically arranged along the first axis of curvature are substantially equal: the measurements V3 and V4 are respectively equal to −0.4 and −0.05 mm.

Another advantage of the manufacturing method described here is that the first layer 12, the second layer 14, and then the photovoltaic module 10, can all be obtained by identical techniques using a mold with rigid parts, typically the same mold whose air gap is varied depending on the part to be obtained, respectively in step E1, E2 and E4.

Electroluminescence imaging after implementation showed that no degradation of the photovoltaic cells 16 had occurred, thus confirming the compatibility of the materials used and the double curvature with the thermocompression assembly technique of step E4 for manufacturing photovoltaic modules 10. The electrical performance of the manufactured modules during the tests is completely acceptable compared with that of standard modules (a maximum power difference of less than 5% as a function of the transmittance of the front face used). The impact tests IK7 in accordance with the specific NF 60068-2-75 standard did not cause any breakage of the photovoltaic cells 16, demonstrating the compatibility of the first layer 12 used as the front face.

It should be noted that the known lamination technique, in addition to the already described drawbacks, would involve complicated management of the forces applied to the front and rear faces of the photovoltaic module to be manufactured, due to the at least one curvature caused by the skew shape to be obtained, which is one of the issues to be solved within the framework of the present invention. The manufacturing method described in this document addresses this issue.

It is emphasized that the values of the different parameters (temperature, time, mechanical pressure), dimensions (thicknesses of the different layers, air gap values, etc.) and choice of materials detailed in this document are not at all arbitrary and were not directly accessible to those skilled in the art. During step E4, the pressure/temperature/air gap trio of the assembly mold 20 was carefully calibrated so as not to damage the photovoltaic cells 16. This degradation could otherwise result from excessive creep of the encapsulant, under the effect of the temperature, the curvature and the adjustment of the thickness of the stack to the predetermined air gap 26 of the assembly mold 20. It could also be linked to a localized overpressure, for example at the connectors, due to the lack of space associated with the fixed predetermined air gap 26 of the mold assembly 20. This pressure/temperature/air gap trio had to be adjusted taking into account analyses, particularly rheological analyses, of the encapsulating materials 181, 182 used and an experimental design on sheets of encapsulating materials integrating unconnected photovoltaic cells 16. Likewise, in order to avoid immediate pressurization, the thickness of the seals 222, 242 of the assembly mold 20 has been adjusted in order to enable sealing without yet being perfectly in contact with the stack. Each seal 222, 242 can have a thickness of 1 cm in its natural state (not crushed) and have a thickness in the range of 7 mm in the closure configuration of the mold.

### NOMENCLATURE

1: photovoltaic module (prior art)
2: front panel (prior art)
3: encapsulating assembly (prior art)
3a: front layer (prior art)
3b: rear layer (prior art)
4: photovoltaic cells (prior art)
4a: front face of the cells (prior art)
4b: rear face of the cells (prior art)
5: rear face (prior art)
6: connecting conductors (prior art)
7: junction box (prior art)
10: photovoltaic module
12: first layer
14: second layer
16: photovoltaic cells
18: encapsulating assembly
181: encapsulating material
182: encapsulating material
20: assembly mold
22: first mold part
220: first impression of the assembly mold
222: first seal
24: second mold part
240: second impression of the assembly mold
242: second seal
26: first predetermined air gap
Tfonc: operating temperature
D1: relative bringing together
D2: relative moving away
P1: first phase
P2: second phase
P3: third phase
P4: fourth phase
E1: step of providing a first layer
E2: step of manufacturing a second layer
E3: step of placing a stack in an assembly mold
E4: assembly step
ÊS: step consisting in heating the assembly mold
E6: step consisting in heating the stack
E7: step of cooling the stack
F0: heat input to the stack
F1: mechanical pressure
F2: heat transfer from the photovoltaic module to the assembly mold
Δ: predetermined period
E10: step consisting in modifying the air gap separating the two preparation mold parts
E11: step of preparing/supplying the first composite material
E12: placing the first composite material from step E11 in a preparation mold
E13: heating the first composite material
E14: applying to the first composite material, by the two preparation mold parts, a mechanical pressure
E20: step consisting in modifying the air gap separating the two manufacturing mold parts
E21: providing the second composite material
E22: placing the second composite material from the step in a manufacturing mold
E23: heating the second composite material
E24: applying to the second composite material, by the two manufacturing mold parts, a mechanical pressure
K1: first value of the air gap
K2: second value of the air gap

1. A method for manufacturing a photovoltaic module, comprising:
E1) providing a first layer having a skew, transparent shape and configured to form a front face of the photovoltaic module configured to receive a light flux,
E2) manufacturing a second layer having a skew shape and configured to form a rear face of the photovoltaic module,
E3) placing a stack in an assembly mold, after E1 and E2, in which:
the stack comprises the first layer, a plurality of photovoltaic cells arranged side by side and electrically connected to each other, the second layer and at least one encapsulating material, at least one encapsulating material and the plurality of photovoltaic cells being located between the first and second layers, and
the assembly mold has an ability to occupy a closure configuration and comprises a first rigid mold part delimiting a first impression with skew shape complementary to the skew shape of the first layer and a second rigid mold part delimiting a second impression with skew shape complementary to the skew shape of the second layer, the first mold part and the second mold part, in the closure configuration of the assembly mold, are spaced apart by a predetermined air gap and delimit between them a cavity configured to receive the stack,
E4) assembly, implemented after E3, in which the closure configuration of the assembly mold is adopted, a temperature within the stack is maintained at an operating temperature comprised between 70° C. and 180° C. during an assembly period adapted as a function of the at least one encapsulating material so that the at least one encapsulating material undergoes melting at least partially and to create an encapsulating assembly configured to adhere to the plurality of photovoltaic cells and to the first layer and/or to the second layer.

2. The manufacturing method according to claim 1, wherein the first layer is formed of a thermoplastic material.

3. The manufacturing method according to claim 2, wherein the first layer is a first composite material formed based on a first polymer and first fibers, the first polymer being selected from: ethylene chlorotrifluoroethylene, fluorinated ethylene propylene, ethylene tetrafluoroethylene, polyvinylidene fluoride, polymethyl methacrylate, polycarbonate, polyethylene terephthalate, polyamide, styrene-acrylonitrile, polystyrene, and
the first fibers are selected from glass, aramid fibers and/or natural fibers.

4. The manufacturing method according to claim 3, wherein the first polymer is polycarbonate or styrene-acrylonitrile and the first fibers are glass fibers.

5. The manufacturing method according to claim 3, wherein E1 comprises:
E11) preparing the first composite material, in the form of a fiber-reinforced thermoplastic composite plate,
E12) placing the first composite material in a preparation mold, the preparation mold having an ability to occupy a closure configuration and comprising two rigid preparation mold parts and delimiting two preparation impressions with skew shape complementary to the skew shape of the first layer, the two preparation mold parts, in the closure configuration of the preparation mold, are spaced apart by a predetermined air gap and delimit between them a cavity configured to receive the first composite material,
E13) heating the first composite material to a temperature greater than or equal to a glass transition temperature of the first composite material, a difference between the temperature and the glass transition temperature being comprised between 0 and 20° C.,
E14) applying to the first composite material, by the two preparation mold parts, a mechanical pressure greater than or equal to 5 bars by placing the preparation mold in the closure configuration, while controlling cooling until reaching a temperature comprised between 50° C. and 150° C.

6. The manufacturing method according to claim 5, wherein the two preparation mold parts consist respectively of the first and second mold parts of the assembly mold, E1 comprising E10 consisting in modifying the air gap separating the two preparation mold parts in the closure configuration of the preparation mold in E14, relative to the air gap present in E4 in the closure configuration of the assembly mold.

7. The manufacturing method according to claim 1, wherein the first layer has a thickness smaller than 1.5 mm.

8. The method according to claim 1, wherein the second layer is made of a thermoplastic material.

9. The manufacturing method according to claim 8, wherein the second layer is a second composite material formed based on a second polymer and second fibers,
the second polymer being selected from: polycarbonate, polymethyl methacrylate, thermoplastic polyurethane, polyetheretherketone, polyetherketoneketone, polyphenylene sulfide, polyamide, polystyrene, and
the fibers being selected from glass, carbon, aramid fibers and/or natural fibers including hemp, linen and/or silk.

10. The manufacturing method according to claim 9, wherein the second polymer is thermoplastic polyurethane, polycarbonate, or polyamide, and the second fibers are glass fibers.

11. The manufacturing method according to claim 9, wherein E2 comprises:
E21) providing the second composite material,
E22) placing the second composite material in a manufacturing mold, the manufacturing mold having an ability to occupy a closure configuration and comprising two rigid manufacturing mold parts and delimiting two manufacturing impressions of skew shape complementary to the skew shape of the second layer, the two manufacturing mold parts, in the closure configuration of the manufacturing mold, are spaced apart by a predetermined air gap and delimit between them a cavity configured to receive the second composite material,
E23) heating the second composite material to a temperature within 10° C. of a glass transition temperature of the second material,
E24) applying to the second composite material, by the two manufacturing mold parts, a mechanical pressure greater than or equal to 5 bars by placing the manufacturing mold in the closure configuration, while controlling cooling until reaching a temperature comprised between 50° C. and 150° C.

12. The manufacturing method according to claim 11, wherein the two manufacturing mold parts consist respectively of the first and second mold parts of the assembly mold, E2 comprising E20 consisting in modifying the air gap separating the two manufacturing mold parts in the closure configuration of the manufacturing mold in E24, relative to the air gap present in E4 in the closure configuration of the assembly mold.

13. The manufacturing method according to claim 1, wherein the second layer has a thickness smaller than 2 mm.

14. The manufacturing method according to claim 1, wherein during E4, a pressure of the gas present in the cavity of the assembly mold is maintained, during the assembly period, below −0.5 bar.

15. The manufacturing method according to claim 1, wherein E4 comprises E41 during which the first and second mold parts of the assembly mold exert, on the stack, a mechanical pressure lower than or equal to 5 bars.

16. The manufacturing method according to claim 15, wherein E41 begins after the operating temperature is reached, after a predetermined non-zero period comprised between 0.5 min and 2 min.

17. The manufacturing method according to claim 15, wherein E41 is implemented during a period comprised between 30 s and 10 min.

18. The manufacturing method according to claim 1, comprising E5 consisting in heating the assembly mold to a temperature greater than or equal to the operating temperature, E5 being implemented before E4.

19. The manufacturing method according to claim 1, comprising E6 consisting in heating the stack using an infrared heat source, E6 being carried out after E3 and before E4.

20. The manufacturing method according to claim 1, comprising E7 comprising cooling the stack, E7 being performed while the first and second mold parts of the mold assembly exert, on the stack, a mechanical pressure lower than or equal to 5 bars.
